(19) United States
(12) Patent Application Publication
(10) Pub. No.: US 2024/0016041 A1
(43) Pub. Date: Jan. 11, 2024

(54) COLOR CONVERSION SUBSTRATE AND DISPLAY DEVICE INCLUDING THE SAME

(71) Applicant: Samsung Display Co., LTD., Yongin-si (KR)

(72) Inventors: SUN-KYU JOO, Suwon-si (KR); KEUNCHAN OH, Hwaseong-si (KR); TAIMEI KODAIRA, Hwaseong-si (KR); SANGJI PARK, Yongin-si (KR); DOKYUNG YOUN, Suwon-si (KR); WOO-MAN JI, Anyang-si (KR); TAE HYUNG HWANG, Seoul (KR)

(21) Appl. No.: 18/311,755

(22) Filed: May 3, 2023

(30) Foreign Application Priority Data
Jul. 7, 2022 (KR) 10-2022-0083819

(51) Int. Cl. H10K 59/80; H10K 59/35

(52) U.S. Cl. CPC H10K 59/877; H10K 59/35

(57) ABSTRACT

A color conversion substrate includes: a blue color filter on an upper substrate; a first color filter on the blue color filter, and exposing the blue color filter in a blue opening area; a partition on the blue color filter and the first color filter, and surrounding the blue opening area; a first color conversion pattern on the first color filter, overlapping with the first color filter, and accommodated by the partition; and a filler on the blue color filter, accommodated by the partition in the blue opening area, and covering the first color conversion pattern.

### CROSS-REFERENCE TO RELATED APPLICATION(S)

This application claims priority to and the benefit of Korean Patent Application No. 10-2022-0083819, filed on Jul. 7, 2022, in the Korean Intellectual Property Office (KIPO), the entire disclosure of which is incorporated by reference herein.

### BACKGROUND

### 1. Field

Aspects of embodiments of the present disclosure relate to a color conversion substrate, and a display device including the color conversion substrate.

### 2. Description of the Related Art

A display device includes a light emitting layer, and a plurality of color conversion patterns. The light emitting layer emits light, and the color conversion patterns convert the color of the emitted light.

The color conversion patterns may include quantum dots, and may be divided into a red color conversion pattern, a green color conversion pattern, and a scattering pattern (or a blue color conversion pattern). The red color conversion pattern implements a red pixel, the green color conversion pattern implements a green pixel, and the scattering pattern implements a blue pixel.

The above information disclosed in this Background section is for enhancement of understanding of the background of the present disclosure, and therefore, it may contain information that does not constitute prior art.

### SUMMARY

One or more embodiments of the present disclosure are directed to a color conversion substrate.

One or more embodiments of the present disclosure are directed to a display device including the color conversion substrate.

According to one or more embodiments of the present disclosure, a color conversion substrate includes: a blue color filter on an upper substrate; a first color filter on the blue color filter, and exposing the blue color filter in a blue opening area; a partition on the blue color filter and the first color filter, and surrounding the blue opening area; a first color conversion pattern on the first color filter, overlapping with the first color filter, and accommodated by the partition; and a filler on the blue color filter, accommodated by the partition in the blue opening area, and covering the first color conversion pattern.

In an embodiment, the blue opening area may not overlap with a color conversion pattern.

In an embodiment, the color conversion substrate may further include: a refractive layer on the blue color filter; a protective layer on the refractive layer; and a capping layer on the partition and the first color conversion pattern, and contacting the protective layer in the blue opening area.

In an embodiment, the blue color filter may include a scattering particle.

In an embodiment, the scattering particle may include a titanium dioxide (TiO₂) particle.

In an embodiment, a content of the titanium dioxide particle may be less than about 8.5 weight percent (wt %).

In an embodiment, a size of the titanium dioxide particle may be about 100 nanometers (nm) or more and about 200 nm or less.

In an embodiment, the color conversion substrate may further include: a second color filter on the first color filter, and exposing the blue color filter in the blue opening area; and a second color conversion pattern on the second color filter, accommodated by the partition, and covered by the filler.

In an embodiment, the filler may include an organic material.

According to one or more embodiments of the present disclosure, a color conversion substrate includes: a blue color filter on an upper substrate, and including a titanium dioxide (TiO₂) particle; a first color filter on the blue color filter, and exposing a blue opening area of the blue color filter; a second color filter on the first color filter, and exposing the blue opening area of the blue color filter; a partition on the blue color filter, the first color filter, and the second color filter, and surrounding the blue opening area; and a first color conversion pattern on the first color filter, overlapping with the first color filter, and accommodated by the partition.

In an embodiment, a content of the titanium dioxide particle may be less than about 8.5 wt %.

In an embodiment, a size of the titanium dioxide particle may be about 100 nm or more and about 200 nm or less.

According to one or more embodiments of the present disclosure, a display device includes: a blue pixel electrode on a lower substrate, and overlapping with a blue opening area; a first pixel electrode at the same layer as that of the blue pixel electrode; a light emitting layer on the blue pixel electrode and the first pixel electrode; a filler on the light emitting layer; a partition on the filler, surrounding the blue opening area, and accommodating the filler in the blue opening area; a first color conversion pattern on the filler, overlapping with the first pixel electrode, and accommodated by the partition; a blue color filter on the filler, and overlapping with the blue opening area; and a first color filter on the first color conversion pattern, overlapping with the first color conversion pattern, and exposing the blue color filter in the blue opening area.

In an embodiment, the blue opening area may not overlap with a color conversion pattern.

In an embodiment, the blue color filter may include a scattering particle.

In an embodiment, the scattering particle may include a titanium dioxide (TiO₂) particle.

In an embodiment, a content of the titanium dioxide particle may be less than about 8.5 wt %.

In an embodiment, a size of the titanium dioxide particle may be about 100 nm or more and about 200 nm or less.

In an embodiment, the filler may include an organic material.

In an embodiment, the light emitting layer may include: a first blue light emitting layer on the blue pixel electrode and the first pixel electrode; a second blue light emitting layer on the first blue light emitting layer; a third blue light emitting layer on the second blue light emitting layer; and a green light emitting layer on the third blue light emitting layer.

According to one or more embodiments of the present disclosure, the display device may include a blue color filter including the scattering particle, the partition disposed on the blue color filter, and surrounding (e.g., around a periphery of) the blue opening area, and the filler disposed on the blue color filter, accommodated by the partition in the blue opening area, and covering the first color conversion pattern. The blue opening area may not overlap with the color conversion pattern. In other words, the color conversion pattern may not be formed in the blue opening area.

According to one or more embodiments of the present disclosure, as the color conversion pattern is not formed in the blue opening area, the overall luminance of light passing through the blue color filter may be increased. Also, as the blue color filter includes the scattering particles, a front luminance of light passing through the blue color filter may decrease, and a lateral luminance may increase. Accordingly, white angular dependency (WAD) of the display device may be improved.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a perspective view illustrating a display device according to an embodiment.

FIG. 2 is a block diagram illustrating a light emitting substrate included in the display device of FIG. 1.

FIG. 3 is a circuit diagram illustrating a pixel circuit and a light emitting device included in the light emitting substrate of FIG. 2.

FIG. 4 is a cross-sectional view illustrating the light emitting substrate of FIG. 2.

FIG. 5 is a plan view illustrating a color conversion substrate included in the display device of FIG. 1.

FIG. 6 is a cross-sectional view illustrating the color conversion substrate of FIG. 5.

FIG. 7 is a cross-sectional view illustrating the display device of FIG. 1.

FIG. 8 is a graph illustrating luminance of light measured according to an angle of light emitted through a blue color filter.

FIGS. 9-18 are cross-sectional views illustrating a method of manufacturing the color conversion substrate of FIG. 6.

FIG. 19 is a perspective view illustrating a display device according to another embodiment.

FIG. 20 is a cross-sectional view illustrating a color conversion substrate included in the display device of FIG. 19.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

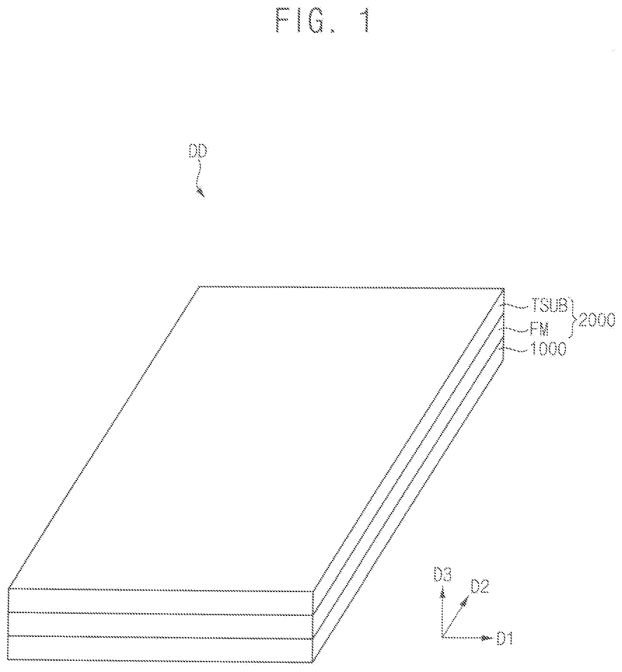

FIG. 1 is a perspective view illustrating a display device according to an embodiment.

Referring to FIG. 1, a display device DD according to an embodiment may include a light emitting substrate 1000 and a color conversion substrate 2000. The color conversion substrate 2000 may include a filler FM and an upper substrate TSUB.

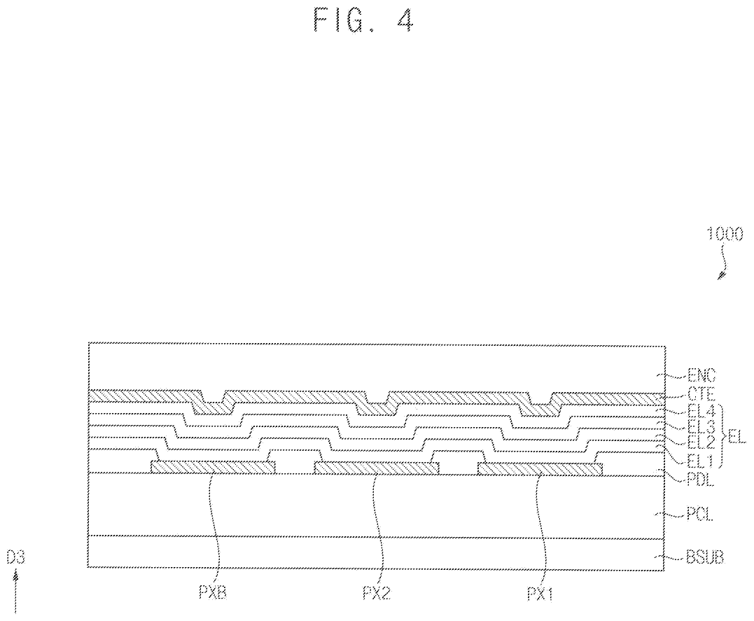

The light emitting substrate 1000 may generate and emit light. In an embodiment, the light emitting substrate 1000 may include a pixel circuit layer (e.g., a pixel circuit layer PCL of FIG. 4) and a light emitting layer (e.g., a light emitting layer EL of FIG. 4). The pixel circuit layer PCL may generate a driving current, and the light emitting layer EL may emit light based on the driving current.

The color conversion substrate 2000 may be disposed on the light emitting substrate 1000. In an embodiment, the color conversion substrate 2000 may convert the color of the light emitted from the light emitting substrate 1000. Accordingly, color reproducibility of the display device DD may be improved.

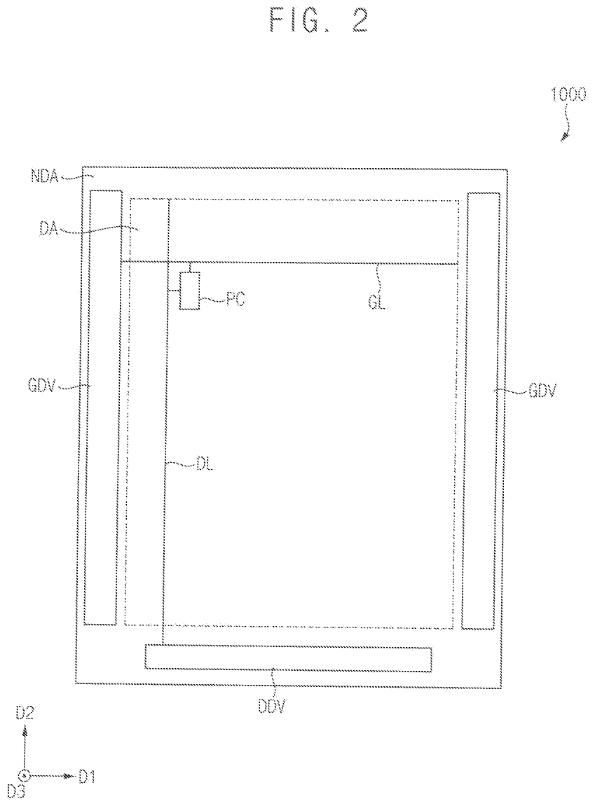

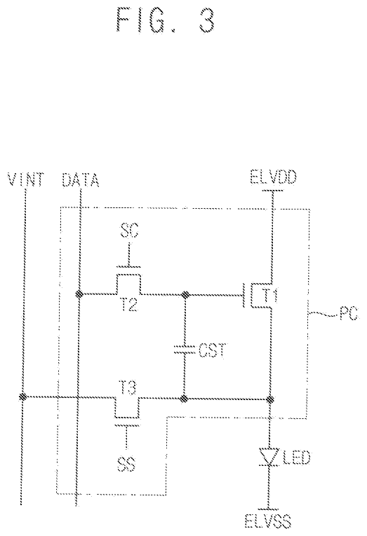

FIG. 2 is a block diagram illustrating a light emitting substrate included in the display device of FIG. 1. FIG. 3 is a circuit diagram illustrating a pixel circuit and a light emitting device included in the light emitting substrate of FIG. 2. FIG. 4 is a cross-sectional view illustrating the light emitting substrate of FIG. 2.

Referring to FIG. 2, the light emitting substrate 1000 may be divided into a display area DA and a non-display area NDA. An image may be displayed in the display area DA, and the non-display area NDA may be positioned to surround (e.g., around a periphery of) at least a portion of the display area DA.

A pixel circuit PC may be disposed at (e.g., in or on) the display area DA. The pixel circuit PC may be electrically connected to a gate line GL extending in a first direction D1, and a data line DL extending in a second direction D2 crossing the first direction. The pixel circuit PC may generate the driving current.

A gate driver GDV and a data driver DDV may be disposed at (e.g., in or on) the non-display area NDA.

The gate driver GDV may generate a gate signal (e.g., a first gate signal SC and a second gate signal SS of FIG. 3). The gate signal may be transmitted to the pixel circuit PC through the gate line GL.

The data driver DDV may generate a data voltage (e.g., the data voltage DATA of FIG. 3). The data voltage may be transmitted to the pixel circuit PC through the data line DL.

Referring to FIG. 3, the pixel circuit PC may include a first transistor T1, a second transistor T2, a third transistor T3, and a storage capacitor CST. The pixel circuit PC may be electrically connected to a light emitting diode LED. The pixel circuit PC may generate the driving current, and the light emitting diode LED may emit light in response to the driving current.

The first transistor T1 may include a gate terminal, a first terminal, and a second terminal. The gate terminal may be electrically connected to the second transistor T2. The first terminal may receive a first voltage ELVDD. The second terminal may be electrically connected to the light emitting diode LED. The first transistor T1 may generate the driving current.

The second transistor T2 may include a gate terminal, a first terminal, and a second terminal. The gate terminal may receive the first gate signal SC. The first terminal may receive the data voltage DATA. The second terminal may be electrically connected to the first transistor T1. The second transistor T2 may transmit the data voltage DATA in response to the first gate signal SC.

The third transistor T3 may include a gate terminal, a first terminal, and a second terminal. The gate terminal may receive the second gate signal SS. The first terminal may receive an initialization voltage VINT. The second terminal may be electrically connected to the light emitting diode LED. The third transistor T3 may transmit the initialization voltage VINT in response to the second gate signal SS.

The storage capacitor CST may include a first terminal and a second terminal. The first terminal may be electrically connected to the gate terminal of the first transistor T1. The second terminal may be electrically connected to the second terminal of the first transistor T1.

The light emitting diode LED may include a first terminal and a second terminal. The first terminal may be electrically connected to the first transistor T1. The second terminal may receive a second voltage ELVSS.

Referring to FIG. 4, the light emitting substrate 1000 may include a lower substrate BSUB, a pixel circuit layer PCL, a blue pixel electrode PXB, a first pixel electrode PX1, a second pixel electrode PX2, a pixel defining layer PDL, a light emitting layer EL, a common electrode CTE, and an encapsulation layer ENC.

The lower substrate BSUB may include a transparent material or an opaque material. In an embodiment, examples of the material that may be included in (e.g., used as) the lower substrate BSUB may include glass, quartz, plastic, or the like. These may be used alone or in suitable combinations with each other.

The pixel circuit layer PCL may be disposed on the lower substrate BSUB. The pixel circuit layer PCL may include insulation layers, semiconductor patterns, and conductive patterns. The semiconductor patterns and the conductive patterns may be formed between the insulation layers, and may constitute the aforementioned transistors.

The blue pixel electrode PXB may be disposed on the pixel circuit layer PCL. The blue pixel electrode PXB may be electrically connected to the pixel circuit layer PCL. In an embodiment, the blue pixel electrode PXB may be formed of a metal, an alloy, a conductive metal oxide, a transparent conductive material, or the like. Examples of materials that may be included in (e.g., used as) the blue pixel electrode PXB may include silver (Ag), silver-containing alloys, molybdenum (Mo), molybdenum-containing alloys, aluminum (Al), aluminum-containing alloys, aluminum nitride (AlN), tungsten (W), tungsten nitride (WN), copper (Cu), nickel (Ni), chromium (Cr), chromium nitride (CrN), titanium (Ti), tantalum (Ta), Platinum (Pt), scandium (Sc), indium tin oxide (ITO), indium zinc oxide (IZO), and/or the like. These may be used alone or in suitable combinations with each other. Also, the blue pixel electrode PXB may be formed of a single layer or multilayers.

The first pixel electrode PX1 may be disposed at (e.g., in or on) the same layer as that of the blue pixel electrode PXB. In an embodiment, the first pixel electrode PX1 may be formed together with the blue pixel electrode PXB, and may include the same material as that of the blue pixel electrode PXB.

The second pixel electrode PX2 may be disposed at (e.g., in or on) the same layer as that of the blue pixel electrode PXB and the first pixel electrode PX1. In an embodiment, the second pixel electrode PX2 may be formed together with the blue pixel electrode PXB and the first pixel electrode PX1, and may include the same material as that of the blue pixel electrode PXB and the first pixel electrode PX1.

The pixel defining layer PDL may be disposed on the blue pixel electrode PXB, the first pixel electrode PX1, and the second pixel electrode PX2. An opening exposing the blue pixel electrode PXB, the first pixel electrode PX1, and the second pixel electrode PX2 may be formed in (e.g., may penetrate) the pixel defining layer PDL.

The light emitting layer EL may be disposed on the blue pixel electrode PXB, the first pixel electrode PX1, and the second pixel electrode PX2.

In an embodiment, the light emitting layer EL may include a first blue light emitting layer EL1, a second blue light emitting layer EL2, a third blue light emitting layer EL3, and a green light emitting layer EL4.

In an embodiment, the first blue light emitting layer EL1 may be entirely disposed on the blue pixel electrode PXB, the first pixel electrode PX1, the second pixel electrode PX2, and the pixel defining layer PDL. For example, the first blue light emitting layer EL1 may include an organic material for emitting blue light.

In an embodiment, the second blue light emitting layer EL2 may be disposed on the first blue light emitting layer EL1. For example, the second blue light emitting layer EL2 may include an organic material for emitting blue light.

In an embodiment, the third blue light emitting layer EL3 may be disposed on the second blue light emitting layer EL2. For example, the third blue light emitting layer EL3 may include an organic material for emitting blue light.

In an embodiment, the green light emitting layer EL4 may be disposed on the third blue light emitting layer EL3. For example, the green light emitting layer EL4 may include an organic material for emitting green light.

The common electrode CTE may be disposed on the green light emitting layer EL4. In an embodiment, the common electrode CTE may be formed of a metal, an alloy, a conductive metal oxide, a transparent conductive material, or the like.

The encapsulation layer ENC may be disposed on the common electrode CTE. The encapsulation layer ENC may include at least one inorganic layer, and at least one organic layer. The inorganic layer and the organic layer may be alternately stacked on one another.

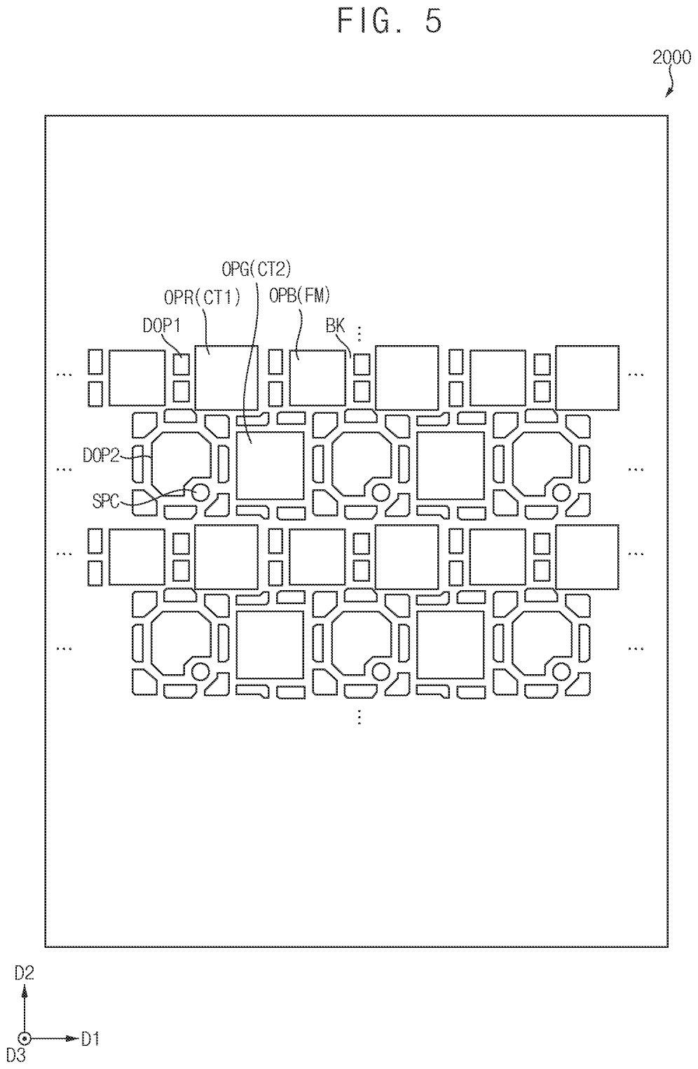

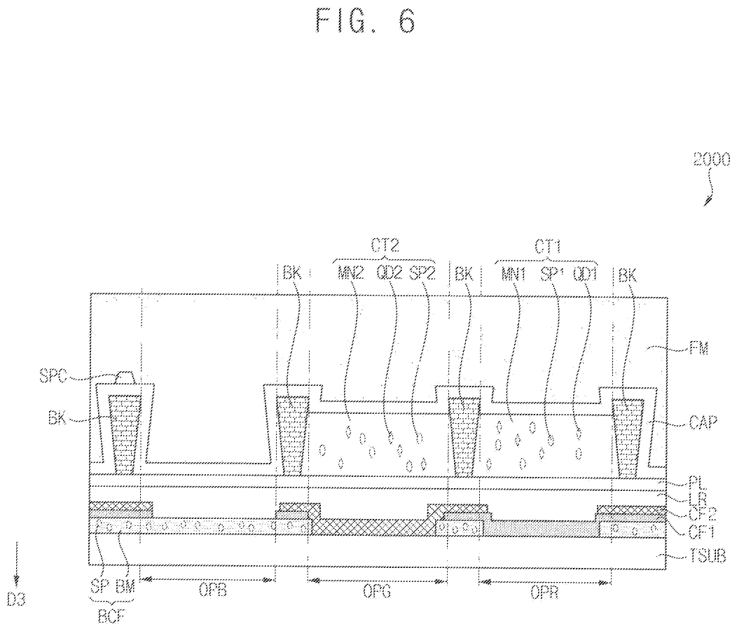

FIG. 5 is a plan view illustrating a color conversion substrate included in the display device of FIG. 1. FIG. 6 is a cross-sectional view illustrating the color conversion substrate of FIG. 5.

Referring to FIG. 5, a partition BK may be formed on the color conversion substrate 2000, and a blue opening area OPB, a red opening area OPR, and a green opening area OPG may be defined by the partition BK.

In an embodiment, the blue opening area OPB, the red opening area OPR, and the green opening area OPG may be arranged in a triangular shape. Also, an area of the blue opening area OPB may be smaller than an area of the red opening area OPR, and an area of the red opening area OPR may be smaller than an area of the green opening area OPG. However, the present disclosure is not limited thereto.

In an embodiment, the filler FM may be accommodated in the blue opening area OPB. For example, the partition BK may be formed to surround (e.g., around a periphery of) the blue opening area OPB, and the filler FM may be accommodated in the blue opening area OPB by the partition BK.

In an embodiment, the first color conversion pattern CT1 may be accommodated in the red opening area OPR. For example, the partition BK may be formed to further surround (e.g., around a periphery of) the red opening area OPB, and the first color conversion pattern CT1 may be accommodated in the red opening area OPR by the partition BK.

In an embodiment, the second color conversion pattern CT2 may be accommodated in the green opening area OPG. For example, the partition BK may be formed to further surround (e.g., around a periphery of) the green opening area OPG, and the second color conversion pattern CT2 may be accommodated in the green opening area OPG by the partition BK.

In an embodiment, at least one first dummy opening DOP1 and at least one second dummy opening DOP2 may be further formed in (e.g., may penetrate) the color conversion substrate 2000. The first dummy opening DOP1 may be adjacent to the blue opening area OPB, the red opening area OPR, the green opening area OPG, or the second dummy opening DOP2. The second dummy opening DOP2 may have an area that is substantially similar to that of the green opening area OPG, and may be adjacent to the green opening area OPG.

Referring to FIG. 6, the color conversion substrate 2000 may include an upper substrate TSUB, a blue color filter BCF, a first color filter CF1, a second color filter CF2, a refractive layer LR, a protective layer PL, the partition BK, the first color conversion pattern CT1, the second color conversion pattern CT2, a capping layer CAP, a spacer SPC, and the filler FM.

The upper substrate TSUB may include a transparent material or an opaque material. In an embodiment, examples of the material that may be included in (e.g., used as) the upper substrate TSUB may include glass, quartz, plastic, or the like. These may be used alone or in suitable combinations with each other.

The blue color filter BCF may be disposed on the upper substrate TSUB. In an embodiment, the blue color filter BCF may transmit light having a suitable wavelength band corresponding to blue.

In an embodiment, the blue color filter BCF may include a base member BM and scattering particles SP.

The base member BM may include an organic material in which a blue pigment (or a blue dye) is dispersed. For example, the organic material included in the base member BM may include an acrylic resin, an epoxy resin, or a polyimide resin.

The scattering particle SP may scatter light. In an embodiment, the scattering particle SP may include a titanium dioxide (TiO₂) particle, a zinc oxide (ZnO) particle, an aluminum oxide (Al₂O₃) particle, a silicon oxide (SiO₂) particle, a hollow silica particle, and/or the like.

When the blue color filter BCF includes the titanium dioxide particle, a content of the titanium dioxide particle included in the blue color filter BCF may be less than about 8.5 wt % (e.g., weight percent). In addition, a size of the titanium dioxide particle included in the blue color filter BCF may be about 100 nm (e.g., nanometers) or more, and about 200 nm or less.

However, the present disclosure is not limited thereto. For example, the content of the titanium dioxide particle and the size of the titanium dioxide particle may be variously modified as needed or desired.

The first color filter CF1 may be disposed on the blue color filter BCF. The first color filter CF1 may expose the blue color filter BCF in the blue opening area OPB. The first color filter CF1 may transmit light having a suitable wavelength band corresponding to red. For example, the first color filter CF1 may include an organic material in which a red pigment (or a red dye) is dispersed.

The second color filter CF2 may be disposed on the first color filter CF1. The second color filter CF2 may expose the blue color filter BCF in the blue opening area OPB, and may expose the first color filter CF1 in the red opening area OPR. The second color filter CF2 may transmit light having a suitable wavelength band corresponding to green. For example, the second color filter CF2 may include an organic material in which a green pigment (or a green dye) is dispersed.

The refractive layer LR may be disposed on the second color filter CF2. The refractive layer LR may entirely cover the blue color filter BCF, the first color filter CF1, and the second color filter CF2. In an embodiment, the refractive layer LR may include a material having a relatively small refractive index or a material having a relatively large refractive index.

The protective layer PL may be entirely disposed on the refractive layer LR. In an embodiment, the protective layer PL may include an inorganic material. For example, the protective layer PL may include silicon oxide (SiO₂), silicon nitride (SiNx), silicon oxynitride (SiON), aluminum oxide (Al₂O₃), titanium dioxide (TiO₂), tantalum dioxide (Ta₂O₅), hafnium dioxide. (HfO₂), zinc dioxide (ZnO₂), or the like.

The partition BK may be disposed on the protective layer PL. The partition BK may be formed to surround (e.g., around peripheries of) the blue opening area OPB, the green opening area OPG, and the red opening area OPR. In an embodiment, the partition BK may include a light blocking material that blocks or absorbs light. For example, the partition BK may include a black pigment, a black dye, chromium (Cr), chromium oxide (CrOx), chromium nitride (CrNx), graphite, or the like.

The first color conversion pattern CT1 may be disposed on the protective layer PL. In an embodiment, the first color conversion pattern CT1 may overlap with the first color filter CF1. Also, the first color conversion pattern CT1 may be accommodated by the partition BK in the red opening area OPR.

In an embodiment, the first color conversion pattern CT1 may include a first monomer MN1, first quantum dots QD1, and first scattering particles SP1.

The first quantum dots QD1 and the first scattering particles SP1 may be dispersed in the first monomer MN1. In an embodiment, the first monomer MN1 may include an epoxy-based monomer, an ester-based monomer, or the like.

The first quantum dots QD1 may convert the color of the incident light to red. For example, the first quantum dots QD1 may be quantum dots selected from the group consisting of a group II-VI compound, a group IV-VI compound, a group IV element, a group IV compound, and a suitable combination thereof.

The first scattering particles SP1 may scatter light. In an embodiment, the first scattering particles SP1 may include titanium dioxide (TiO₂) particles, zinc oxide (ZnO) particles, aluminum oxide (Al₂O₃) particles, silicon oxide (SiO₂) particles, hollow silica particles, and/or the like.

The second color conversion pattern CT2 may be disposed on the protective layer PL. In an embodiment, the second color conversion pattern CT2 may overlap with the second color filter CF2. Also, the second color conversion pattern CT2 may be accommodated by the partition BK in the green opening area OPG.

In an embodiment, the second color conversion pattern CT2 may include a second monomer MN2, second quantum dots QD2, and second scattering particles SP2.

The second quantum dots QD2 and the second scattering particles SP2 may be dispersed in the second monomer MN2. In an embodiment, the second monomer MN2 may include an epoxy-based monomer, an ester-based monomer, or the like.

The second quantum dots QD2 may convert the color of the incident light to green. For example, the second quantum dots QD2 may be quantum dots selected from the group consisting of a group II-VI compound, a group IV-VI compound, a group IV element, a group IV compound, and a suitable combination thereof.

The second scattering particles SP2 may scatter light. In an embodiment, the second scattering particles SP2 may include titanium dioxide (TiO₂) particles, zinc oxide (ZnO) particles, aluminum oxide (Al₂O₃) particles, silicon oxide (SiO₂) particles, hollow silica particles, and/or the like.

The capping layer CAP may be disposed on the partition BK, the first color conversion pattern CT1, and the second color conversion pattern CT2. The capping layer CAP may entirely cover the partition BK, the first color conversion pattern CT1, and the second color conversion pattern CT2.

In an embodiment, the blue opening area OPB may not overlap with the color conversion pattern. In other words, the color conversion pattern may not be formed in the blue opening area OPB. Accordingly, the capping layer CAP may contact the protective layer PL in the blue opening area OPB.

The spacer SPC may be disposed on the capping layer CAP, and may overlap with the partition BK. In an embodiment, the spacer SPC may be formed on the partition BK, and may not overlap with the blue opening area OPB, the green opening area OPG, or the red opening area OPR.

The filler FM may be disposed on the capping layer CAP. The filler FM may cover the first color conversion pattern CT1 and the second color conversion pattern CT2.

In an embodiment, the filler FM may be accommodated by the partition BK in the blue opening area OPB. For example, because the color conversion pattern is not formed in the blue opening area OPB, the filler FM may be accommodated by the partition BK in the blue opening area OPB.

In an embodiment, the filler FM may include an organic material having a relatively large refractive index. For example, the refractive index of the filler FM may be about 1.6 to about 1.8. For example, the filler FM may include a urethane-based resin, an epoxy-based resin, an acrylic resin, and/or the like.

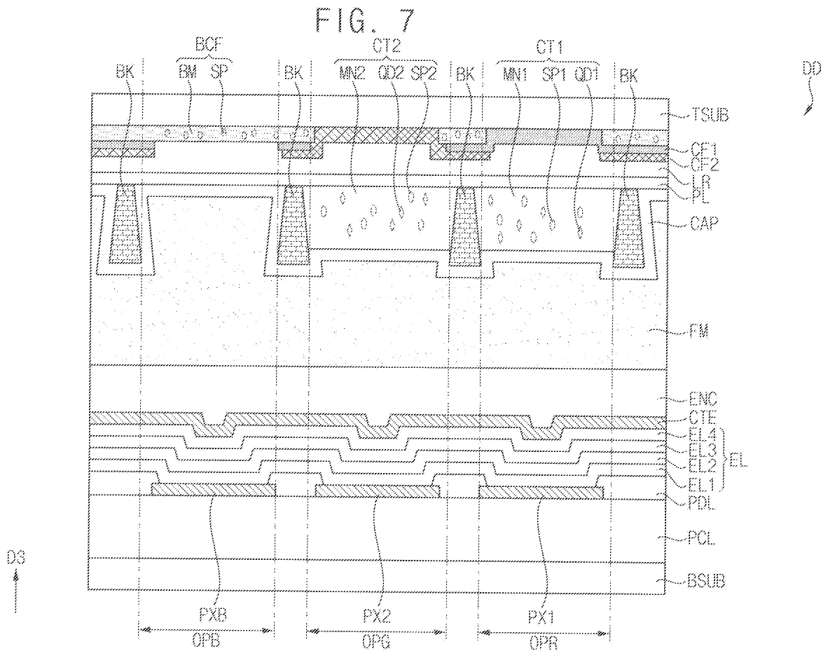

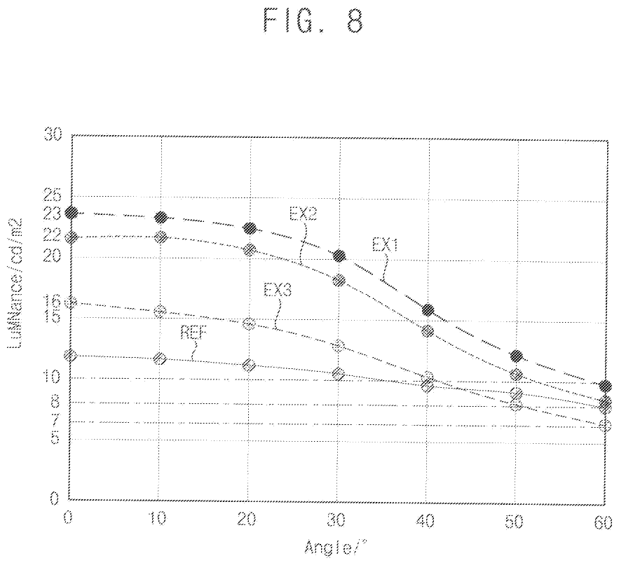

FIG. 7 is a cross-sectional view illustrating the display device of FIG. 1. FIG. 8 is a graph illustrating luminance of light measured according to an angle of light emitted through a blue color filter.

Referring to FIG. 7, light emitted from the light emitting layer EL overlapping with the blue opening area OPB may be emitted through the blue color filter BCF. The light emitted from the light emitting layer EL overlapping with the red opening area OPR may be emitted through the first color conversion pattern CT1 and the first color filter CF1. The light emitted from the light emitting layer EL overlapping with the green opening area OPG may be emitted through the second color conversion pattern CT2 and the second color filter CF2.

As the color conversion pattern is not formed in the blue opening area OPB, the luminance of light passing through the blue color filter BCF may be increased. Also, as the blue color filter BCF includes the scattering particles SP, lateral luminance of light passing through the blue color filter BCF may be increased.

Referring to FIG. 8, the luminance of light is measured according to an angle of the light emitted through the blue color filter BCF.

A reference luminance REF is measured to be approximately 12 cd/m2 at 0 degree (e.g., a front luminance), and approximately 8 cd/m2 at 60 degrees (e.g., a lateral luminance). The reference luminance REF may be defined as a target white angular dependency (WAD).

When the content of the titanium dioxide particle included in the blue color filter BCF is about 2.5%, and the size of the titanium dioxide particle is about 100 nm or about 200 nm, first luminance EX1 is measured. The first luminance EX1 is measured to be approximately 23 cd/m2 at 0 degree, and approximately 10 cd/m2 at 60 degrees.

When the content of the titanium dioxide particle included in the blue color filter BCF is about 3.5%, and the size of the titanium dioxide particle is about 100 nm or about 200 nm, second luminance EX2 is measured. The second luminance EX2 is measured to be approximately 22 cd/m2 at 0 degree, and approximately 8 cd/m2 at 60 degrees.

When the content of the titanium dioxide particle included in the blue color filter BCF is about 8.5%, and the size of the titanium dioxide particle is about 100 nm or about 200 nm, third luminance EX3 is measured. The third luminance EX3 is measured to be approximately 16 cd/m2 at 0 degree, and approximately 7 cd/m2 at 60 degrees.

As the content of the titanium dioxide particle included in the blue color filter BCF is increased, the measured luminance is similar to the reference luminance REF. In other words, as the first luminance EX1 progresses to the third luminance EX3, the measured luminance is similar to the reference luminance REF. Thus, depending on the content of the titanium dioxide particle included in the blue color filter BCF, the front luminance may be decreased, and the lateral luminance may be increased. Accordingly, the WAD of the display device DD may be improved.

However, the present disclosure is not limited thereto. For example, the content of the titanium dioxide particle and the size of the titanium dioxide particle may be variously modified as needed or desired. For example, the content of titanium dioxide particle and the size of the titanium dioxide particle for improving the WAD may be variously modified according to the conditions of light emitted from the light emitting substrate 1000 described above with reference to FIG. 4.

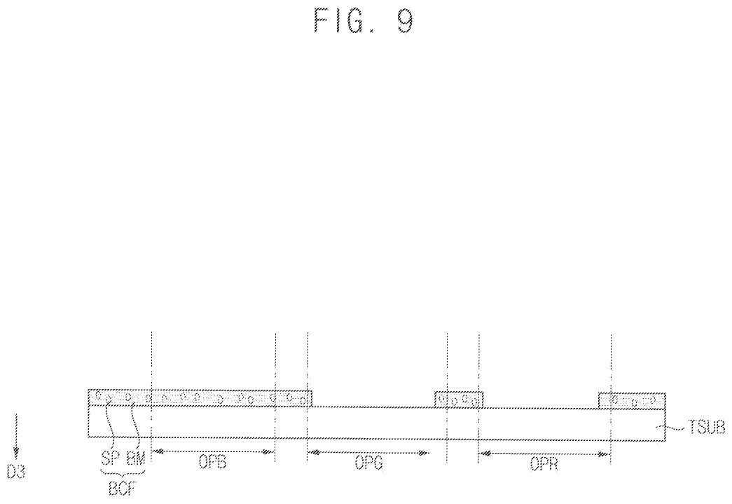

FIGS. 9 through 18 are cross-sectional views illustrating a method of manufacturing the color conversion substrate of FIG. 6.

Referring to FIG. 9, the blue color filter BCF may be formed on the upper substrate TSUB. For example, the blue color filter BCF may expose the upper substrate TSUB in the green opening area OPG and the red opening area OPR. In an embodiment, the blue color filter BCF may be formed through a photoresist process using a mask.

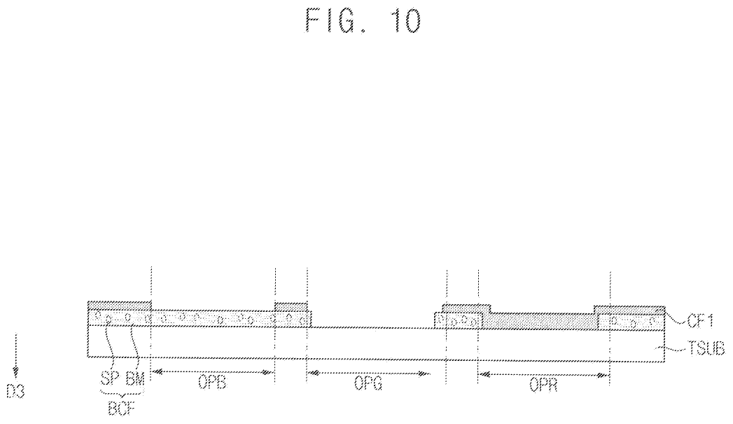

Referring to FIG. 10, the first color filter CF1 may be formed on the blue color filter BCF. For example, the first color filter CF1 may expose the blue color filter BCF in the blue opening area OPB, and may expose the upper substrate TSUB in the green opening area OPG. In an embodiment, the first color filter CF1 may be formed through a photoresist process using a mask.

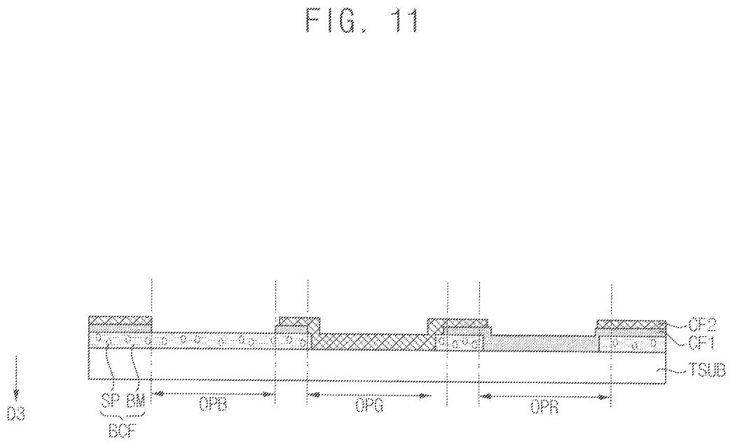

Referring to FIG. 11, the second color filter CF2 may be formed on the first color filter CF1. For example, the second color filter CF2 may expose the blue color filter BCF in the blue opening area OPB, and the first color filter CF1 in the red opening area OPR. In an embodiment, the second color filter CF2 may be formed through a photoresist process using a mask.

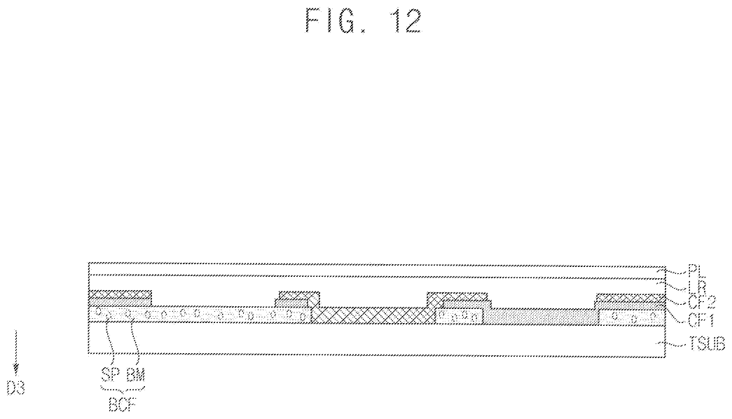

Referring to FIG. 12, the refractive layer LR may be formed on the second color filter CF2, and the protective layer PL may be formed on the refractive layer LR. The refractive layer LR may cover the blue color filter BCF, the first color filter CF1, and the second color filter CF2.

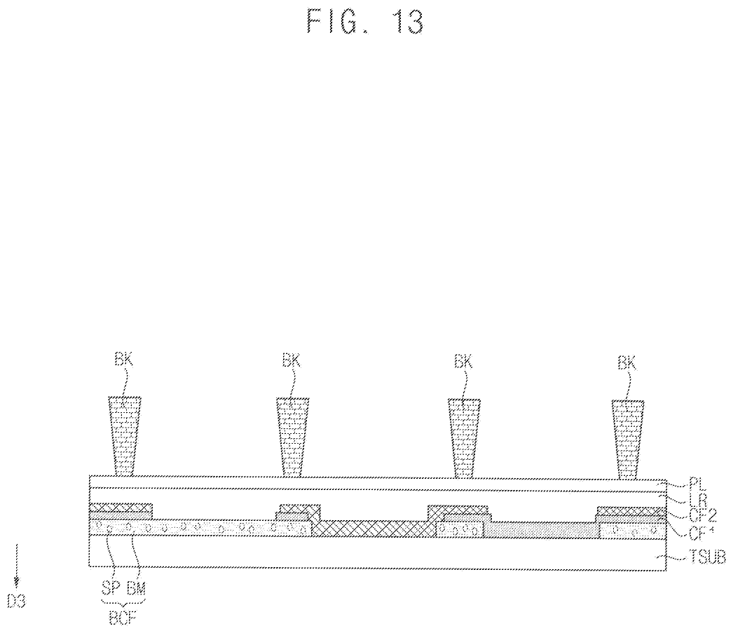

Referring to FIG. 13, the partition BK may be formed on the protective layer PL. For example, the partition BK may be formed at (e.g., in or on) an area where the blue color filter BCF, the first color filter CF1, and the second color filter CF2 overlap with each other. In an embodiment, the partition BK may be formed through a photoresist process using a mask.

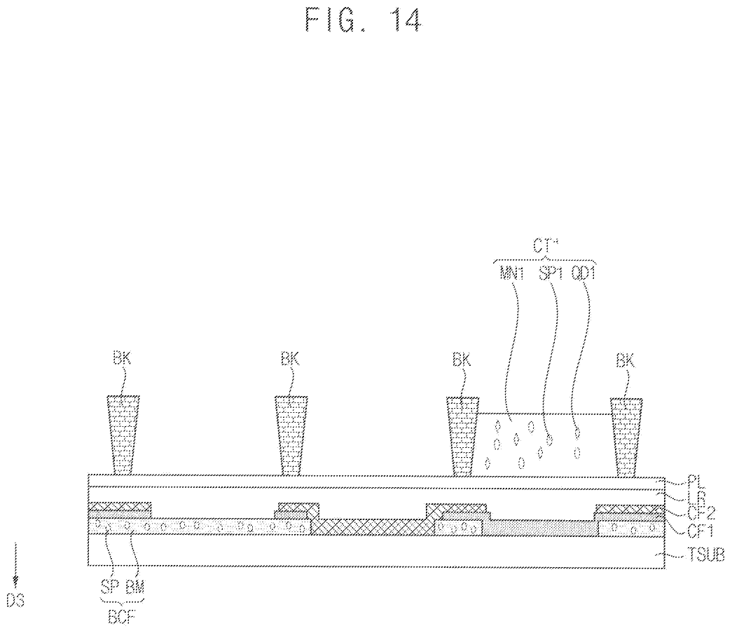

Referring to FIG. 14, the first color conversion pattern CT1 may be formed on the protective layer PL. For example, the first color conversion pattern CT1 may be accommodated by the partition BK in the red opening area OPR. In an embodiment, the first color conversion pattern CT1 may be formed through an inkjet printing process.

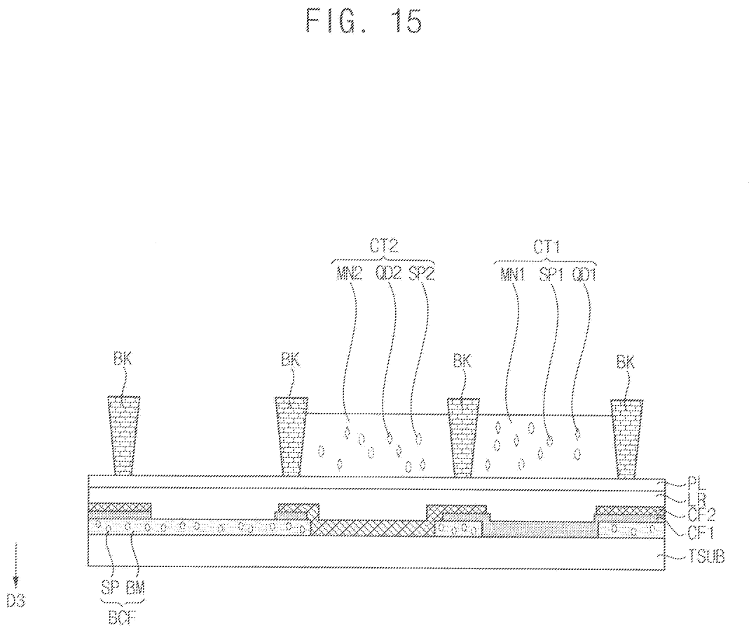

Referring to FIG. 15, the second color conversion pattern CT2 may be formed on the protective layer PL. For example, the second color conversion pattern CT2 may be accommodated by the partition BK in the green opening area OPG. In an embodiment, the second color conversion pattern CT2 may be formed through an inkjet printing process.

In an embodiment, a color conversion pattern may not be formed in the blue opening area OPG. In other words, a process of forming the color conversion pattern overlapping with the blue opening area OPG may be omitted.

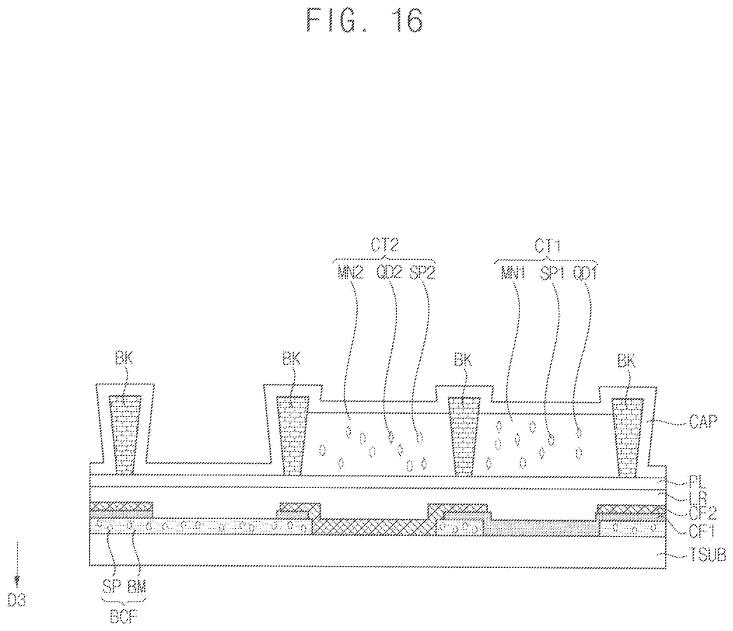

Referring to FIG. 16, the capping layer CAP may be formed on the partition BK, the first color conversion pattern CT1, and the second color conversion pattern CT2. The capping layer CAP may entirely cover the partition BK, the first color conversion pattern CT1, and the second color conversion pattern CT2.

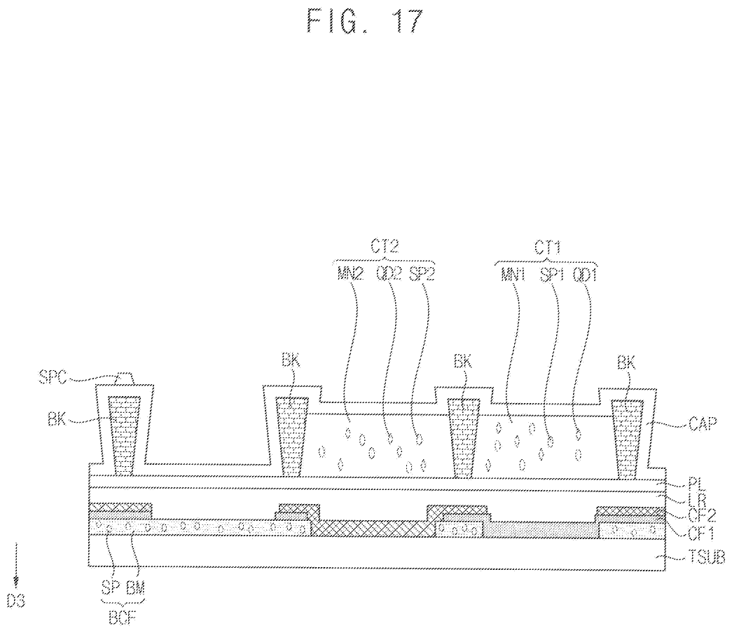

Referring to FIG. 17, the spacer SPC is formed on the capping layer CAP, and may overlap with the partition BK. In an embodiment, the spacer SPC may be formed through a photoresist process using a mask.

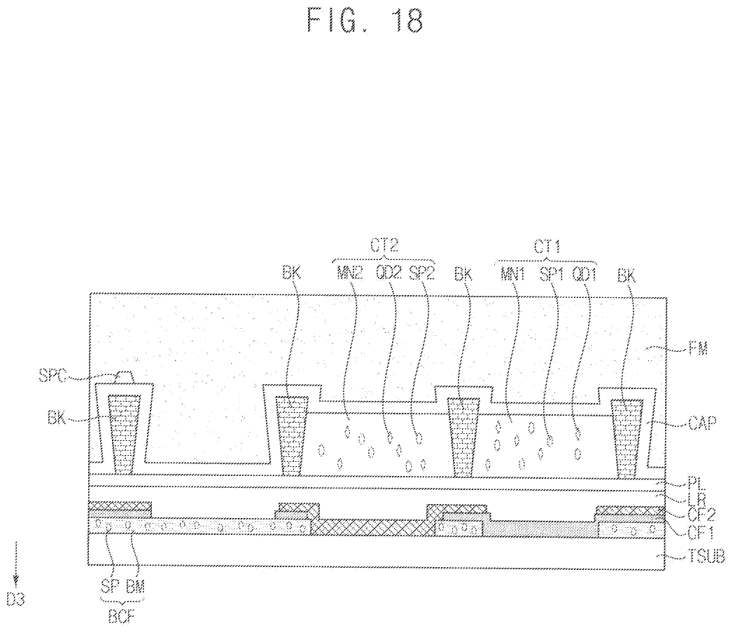

Referring to FIG. 18, the filler FM may be disposed on the capping layer CAP. For example, the filler FM may be accommodated by the partition BK in the blue opening area OPB.

In the method of manufacturing the display device DD of one or more embodiments of the present disclosure, the process of forming the color conversion pattern overlapping with the blue opening area OPG may be omitted. Accordingly, productivity of the display device DD may be improved.

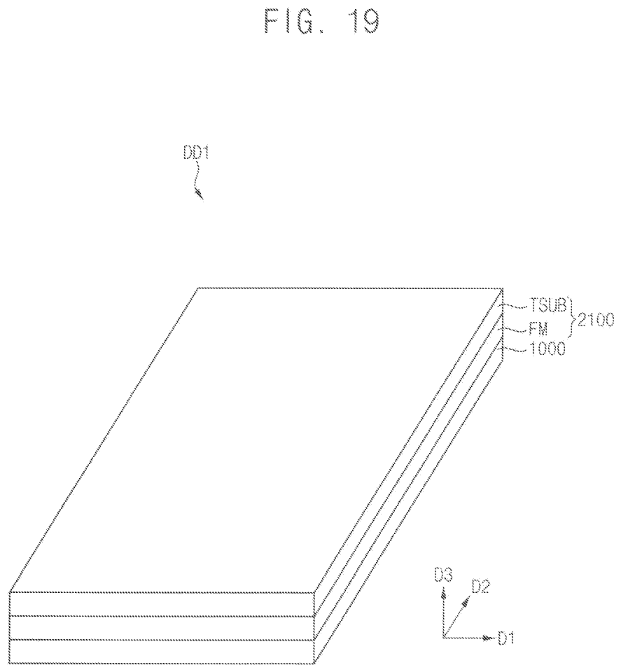

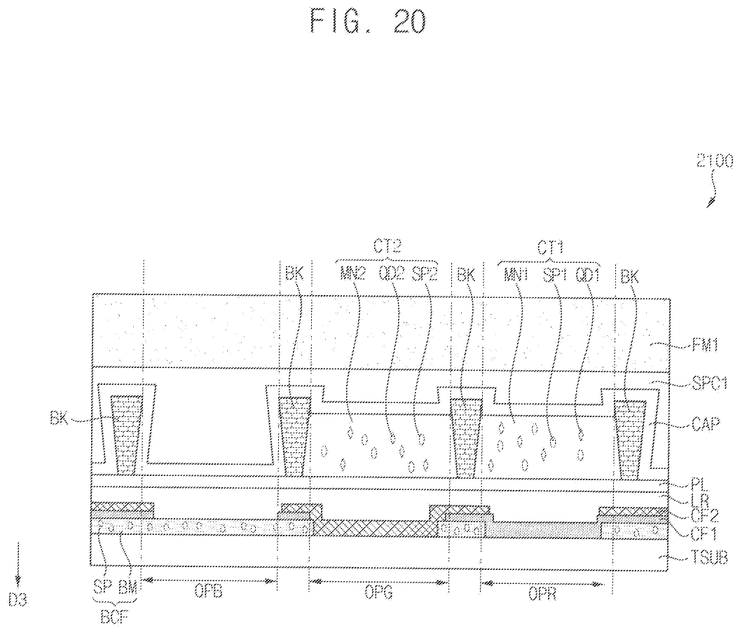

FIG. 19 is a perspective view illustrating a display device according to another embodiment. FIG. 20 is a cross-sectional view illustrating a color conversion substrate included in the display device of FIG. 19.

Referring to FIG. 19, a display device DD1 according to another embodiment may include a light emitting substrate 1000 and a color conversion substrate 2100. The display device DD1 may be the same or substantially the same as the display device DD described above with reference to FIG. 1, except the color conversion substrate 2100 may be different.

Referring to FIG. 20, the color conversion substrate 2100 may include an upper substrate TSUB, a blue color filter BCF, a first color filter CF1, a second color filter CF2, a refractive layer LR, a protective layer PL, the partition BK, a first color conversion pattern CT1, a second color conversion pattern CT2, a capping layer CAP, a spacer SPC1, and a filler FM1. The color conversion substrate 2100 may be the same or substantially the same as the color conversion substrate 2000 described above with reference to FIG. 6, except the spacer SPC1 and the filler FM1 may be different.

In an embodiment, the spacer SPC1 may be entirely disposed on the capping layer CAP. In an embodiment, the spacer SPC1 may be accommodated by the partition BK in the blue opening area OPB. Also, the spacer SPC1 may overlap with the blue opening area OPB, the green opening area OPG, and the red opening area OPR.

The filler FM1 may be disposed on the spacer SPC1. The filler FM1 may be entirely formed on the spacer SPC1.

The display device DD1 may include the spacer SPC1 disposed on an entirely of the capping layer CAP. Accordingly, a mask for forming the spacer SPC1 may be omitted.

The display devices according to the embodiments of the present disclosure may be applied to a display device included in a computer, a notebook, a mobile phone, a smartphone, a smart pad, a PMP, a PDA, an MP3 player, or the like.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A color conversion substrate comprising:
a blue color filter on an upper substrate;
a first color filter on the blue color filter, and exposing the blue color filter in a blue opening area;
a partition on the blue color filter and the first color filter, and surrounding the blue opening area;
a first color conversion pattern on the first color filter, overlapping with the first color filter, and accommodated by the partition; and
a filler on the blue color filter, accommodated by the partition in the blue opening area, and covering the first color conversion pattern.

2. The color conversion substrate of claim 1, wherein the blue opening area does not overlap with a color conversion pattern.

3. The color conversion substrate of claim 1, further comprising:
a refractive layer on the blue color filter;
a protective layer on the refractive layer; and
a capping layer on the partition and the first color conversion pattern, and contacting the protective layer in the blue opening area.

4. The color conversion substrate of claim 1, wherein the blue color filter comprises a scattering particle.

5. The color conversion substrate of claim 4, wherein the scattering particle comprises a titanium dioxide (TiO₂) particle.

6. The color conversion substrate of claim 5, wherein a content of the titanium dioxide particle is less than about 8.5 weight percent (wt %).

7. The color conversion substrate of claim 5, wherein a size of the titanium dioxide particle is about 100 nanometers (nm) or more and about 200 nm or less.

8. The color conversion substrate of claim 1, further comprising:
a second color filter on the first color filter, and exposing the blue color filter in the blue opening area; and
a second color conversion pattern on the second color filter, accommodated by the partition, and covered by the filler.

9. The color conversion substrate of claim 8, wherein the filler comprises an organic material.

10. A color conversion substrate comprising:
a blue color filter on an upper substrate, and comprising a titanium dioxide (TiO₂) particle;
a first color filter on the blue color filter, and exposing a blue opening area of the blue color filter;
a second color filter on the first color filter, and exposing the blue opening area of the blue color filter;
a partition on the blue color filter, the first color filter, and the second color filter, and surrounding the blue opening area; and
a first color conversion pattern on the first color filter, overlapping with the first color filter, and accommodated by the partition.

11. The color conversion substrate of claim 10, wherein a content of the titanium dioxide particle is less than about 8.5 wt %.

12. The color conversion substrate of claim 10, wherein a size of the titanium dioxide particle is about 100 nm or more and about 200 nm or less.

13. A display device comprising:
a blue pixel electrode on a lower substrate, and overlapping with a blue opening area;
a first pixel electrode at the same layer as that of the blue pixel electrode;
a light emitting layer on the blue pixel electrode and the first pixel electrode;
a filler on the light emitting layer;
a partition on the filler, surrounding the blue opening area, and accommodating the filler in the blue opening area;
a first color conversion pattern on the filler, overlapping with the first pixel electrode, and accommodated by the partition;
a blue color filter on the filler, and overlapping with the blue opening area; and
a first color filter on the first color conversion pattern, overlapping with the first color conversion pattern, and exposing the blue color filter in the blue opening area.

14. The display device of claim 13, wherein the blue opening area does not overlap with a color conversion pattern.

15. The display device of claim 13, wherein the blue color filter comprises a scattering particle.

16. The display device of claim 15, wherein the scattering particle comprises a titanium dioxide (TiO₂) particle.

17. The display device of claim 16, wherein a content of the titanium dioxide particle is less than about 8.5 wt %.

18. The display device of claim 16, wherein a size of the titanium dioxide particle is about 100 nm or more and about 200 nm or less.

19. The display device of claim 13, wherein the filler comprises an organic material.

20. The display device of claim 13, wherein the light emitting layer comprises:
a first blue light emitting layer on the blue pixel electrode and the first pixel electrode;
a second blue light emitting layer on the first blue light emitting layer;
a third blue light emitting layer on the second blue light emitting layer; and
a green light emitting layer on the third blue light emitting layer.
